(19) United States
(12) Patent Application Publication
(10) Pub. No.: US 2013/0319523 A1
(43) Pub. Date: Dec. 5, 2013

(54) CONDUCTIVE TRANSPARENT GLASS SUBSTRATE FOR PHOTOVOLTAIC CELL

(71) Applicants: Bart Ballet, Jumet (BE); Otto Agutsson, Jumet (BE); Gaetan Di Stefano, Jumet (BE)

(72) Inventors: Bart Ballet, Jumet (BE); Otto Agutsson, Jumet (BE); Gaetan Di Stefano, Jumet (BE)

(73) Assignee: AGC GLASS EUROPE, Bruxelles (Watermael-Boitsfort) (BE)

(21) Appl. No.: 14/000,040

(22) PCT Filed: Feb. 16, 2012
(86) PCT No.: PCT/EP2012/052715

§ 371 Date: Aug. 16, 2013

(30) Foreign Application Priority Data
Feb. 17, 2011 (BE) BE 2011/0104

(51) Int. Cl. H01L 31/0224; H01L 31/18

(52) U.S. Cl. CPC H01L 31/022466; H01L 31/1884
USPC 136/256; 438/94; 427/74

(57) ABSTRACT

The invention relates to a conductive transparent glass substrate for a photovoltaic cell, that does not comprise a metal layer and comprises, in succession, a sheet of glass, a barrier layer based on oxide, nitride or oxynitride, a conductive functional layer based on doped zinc oxide or doped indium oxide, and a protection layer based on nitride, oxynitride or oxycarbide such that the barrier layer has a thickness that is at least more than, or equal to 10 nm, and, at the most, less than or equal to 100 nm, the functional layer has a thickness that is at least more than or equal to 200 nm and at the most, less than or equal to 1200 nm, and the protection layer has a thickness that is at least more than or equal to 10 nm, and at the most, lower than or equal to 250 nm. The invention also relates to the method of producing said substrate, to the CdTe-based photovoltaic cells incorporating said substrate, and to the method for producing said cells.

### 1. FIELD OF THE INVENTION

The field of the invention is that of conductive transparent glass substrates for a photovoltaic cell, more particularly for a CdTe-based photovoltaic cell. The expression “CdTe-based photovoltaic cell” is understood to mean a photovoltaic cell comprising at least one photoelectrically active layer made of CdTe, it being possible for said CdTe layer to be alone or combined with a photoelectrically active layer of a different chemical nature selected from amorphous silicon, microcrystalline silicon, a Copper-Indium-Gallium-Selenium alloy, it being possible for the concentration of indium and gallium to vary from pure copper indium selenide to pure copper gallium selenide, these alloys being known to a person skilled in the art under the acronym CIGS, so as to form what is known as a tandem photovoltaic cell, such as for example a tandem CdTe/CIGS or CdTe/amorphous or microcrystalline silicon cell.

More specifically, the invention relates to a conductive transparent glass substrate for a photovoltaic cell, more particularly for a CdTe-based photovoltaic cell, successively comprising a glass sheet, a layer referred to as a barrier layer based on oxide, nitride or oxynitride, a conductive functional layer based on doped zinc oxide or doped indium oxide and a layer referred to as a protective layer based on nitride, oxynitride or oxycarbide, said transparent glass substrate not comprising a metallic layer. Moreover, the invention also relates to the processes for manufacturing said substrate. The invention also relates to photovoltaic cells, more particularly to CdTe-based photovoltaic cells, in which said substrate is incorporated and also to the processes for manufacturing these cells.

### 2. SOLUTION OF THE PRIOR ART

The conductive transparent glass substrate for a photovoltaic cell generally consists of a glass sheet coated with a stack of layers, among which at least two types of layers are distinguished: layers referred to as functional layers, based on a conductive oxide, which contribute to the electrical conductivity properties of the substrate and protective layers, generally made of transparent dielectric materials, the role of which is to provide chemical and/or mechanical protection of the functional layers. Specifically, a durability of the conductive transparent glass substrate is required, as much from a physiochemical viewpoint linked to a tolerance with respect to chemical and atmospheric agents (for example a corrosion resistance), as a mechanical requirement, linked to the resistance to deterioration during its storage, its handling or during the manufacture of photovoltaic cells from said substrate.

Moreover, in the field of photovoltaic cells, more particularly CdTe-based photovoltaic cells, it is necessary to resort to a deposition process at high temperatures and/or an annealing heat treatment of the layers constituting the cells. For example, the typical structure of a photovoltaic cell is in the form of a stack successively comprising a glass sheet, an oxide-based conductive functional layer, a CdS layer, a CdTe layer and a counter electrode. The CdTe layer is the photoelectrically active layer. The CdS layer acts as a potential barrier (CdS—CdTe heterojunction) and prevents direct contact between the CdTe layer and the oxide-based conductive functional layer. The CdS layer also acts as a light aperture and does not exhibit photoelectric activity. It hence appears that a compromise must be found as regards the thickness of the CdS layer. It must be thick enough to be of good quality, continuous and to limit direct contact between the CdTe layer and the oxide-based conductive functional layer and at the same time be thin enough to limit light absorption. Obtaining the CdS and CdTe layers may require heating the conductive transparent glass substrate and/or a step of annealing the CdS and/or CdTe layers at a temperature between 400° C. and 600° C. It is therefore necessary that all of the materials constituting the conductive transparent glass substrate do not suffer a deterioration of their properties linked to this process of annealing or of depositing CdS and/or CdTe layers, more particularly a deterioration of the electrical properties of said substrate, or even advantageously that they exhibit an improvement in their properties, in particular their electrical properties, following the process for annealing or depositing the CdS and/or CdTe layers.

Document US 2007/0029186 A1 describes a substrate that may undergo a tempering heat treatment without deterioration of the electrical properties of the functional layer based on a conductive oxide. The conductive transparent glass substrate consists of a glass sheet, a barrier layer made of dielectric materials, a functional layer made of a conductive oxide and a protective layer made of inorganic materials such as Si₃N₄. The conductive transparent glass substrate may be used equally as an electrode for a solar cell, for deicing motor vehicle glazing or for oven doors. However, the solution described only enables a maintenance of the electrical properties of the functional layer and furthermore does not disclose any thickness value for each of the layers. Moreover, the solution proposed is not specific to photovoltaic cells, more particularly to CdTe-based photovoltaic cells. Indeed, no optimization of the thicknesses of the various barrier, functional and protective layers is carried out with a view to insertion within a photovoltaic cell, more particularly within a CdTe-based photovoltaic cell in order to obtain good light transmission in the range of wavelengths specific to photovoltaic cells (400-800 nm) through the substrate to the photoelectrically active layer. The expression “photoelectrically active layer” is understood to mean the layer which, exposed to light (photon), produces electricity. Furthermore, no optimization of the protective layer both from an electrical resistivity viewpoint but also from a roughness viewpoint is reported. Moreover, no optimization of the protective layer is suggested in order to limit the contact between the CdTe layer and the oxide-based conductive functional layer.

Document WO 03/093185 A1 also discloses a glass substrate that may also undergo a tempering or bending heat treatment corresponding to temperatures of the order of 500° C. to 700° C., but also treatments corresponding to temperatures of the order of 250° C. to 350° C., without deterioration of the electrical properties of the functional layer based on a conductive oxide. The conductive transparent glass substrate consists of a glass sheet, a barrier layer, an oxide-based functional layer having a thickness between 400 nm and 1100 nm, a thin metallic layer having a thickness of between 1.5 nm and 10 nm and a protective layer based on metal oxides, metal oxynitride or metal nitride having a thickness between 35 nm and 100 nm. Through its electrical and optical properties, the solution disclosed is not specific to photovoltaic cells, more particularly to CdTe-based photovoltaic cells, it being possible for the conductive transparent glass substrate to be used indiscriminately within a photovoltaic cell, an electrochromic cell, a liquid crystal display, etc. Moreover, no optimization of the thicknesses of the various layers has also been carried out with a view to insertion within a photovoltaic cell, more particularly within a CdTe-based photovoltaic cell in order to obtain good light transmission in the range of wavelengths specific to photovoltaic cells through the substrate to the photoelectrically active layer. Furthermore, no optimization of the protective layer both from an electrical resistivity viewpoint but also from a roughness viewpoint is reported. Moreover, no optimization of the protective layer is suggested in order to limit the contact between the CdTe layer and the oxide-based conductive functional layer.

### 3. OBJECTIVE OF THE INVENTION

The objective of the invention is in particular to overcome these drawbacks of the prior art.

More specifically, one objective of the invention, in at least one of its embodiments, is to provide a conductive transparent glass substrate for a photovoltaic cell, more particularly for a CdTe-based photovoltaic cell, having good physiochemical resistance and mechanical strength. More particularly, it is to provide a conductive transparent glass substrate for a photovoltaic cell, more particularly for a CdTe-based photovoltaic cell, that may undergo a heat treatment, said heat treatment not resulting in a reduction of the electrical properties of the substrate, or even improving them, even significantly.

Moreover, the invention makes it possible to provide a conductive transparent glass substrate for a photovoltaic cell, more particularly for a CdTe-based photovoltaic cell having a reduced thickness of the CdS layer, with the advantage of reducing the light absorption thereby, while maintaining limited direct electrical contact between the conductive functional layer and the CdTe, owing to a protective layer selected and adapted for this purpose.

Another objective of the invention, in at least one of its embodiments, is to implement a process for manufacturing a conductive transparent glass substrate for a photovoltaic cell, more particularly for a CdTe-based photovoltaic cell, said process representing great flexibility.

The invention, in at least one of its embodiments, also has the objective of providing a CdTe-based photovoltaic cell.

Moreover, another objective of the invention, in at least one of its embodiments, is to implement a process for obtaining a CdTe-based photovoltaic cell that is easy and flexible.

### 4. SUMMARY OF THE INVENTION

In accordance with one particular embodiment, the invention relates to a conductive transparent glass substrate for a photovoltaic cell, more particularly for a CdTe-based photovoltaic cell, said conductive transparent glass substrate not comprising a metallic layer and successively comprising a glass sheet, a first barrier layer based on oxide, nitride or oxynitride, preferably based on nitride, a conductive functional layer based on doped zinc oxide or doped indium oxide, preferably based on doped zinc oxide, and a protective layer based on nitride, oxynitride or oxycarbide, preferably based on nitride, said layers forming the cathode part of the photovoltaic cell.

According to the invention, such a conductive transparent glass substrate comprises a first barrier layer based on oxide, nitride or oxynitride, preferably based on nitride, having a thickness at least greater than or equal to 10 nm and at most less than or equal to 100 nm, a conductive functional layer based on doped zinc oxide or doped indium oxide, preferably based on doped zinc oxide, having a thickness at least greater than or equal to 200 nm, preferably greater than or equal to 300 nm and at most less than or equal to 1200 nm and a protective layer based on nitride, oxynitride or oxycarbide, preferably based on nitride, having a thickness at least greater than or equal to 10 nm, preferably at least greater than or equal to 40 nm, and at most less than or equal to 250 nm.

The general principle of the invention is based on the optimization of the thicknesses and the selection of the compounds constituting the first barrier layer, the conductive functional layer and the protective layer so as to obtain a conductive transparent glass substrate having, on the one hand, a mean transparency of at least 80%, preferably of at least 90%, in the wavelength range extending from 400 nm to 1100 nm when this substrate is inserted in a photovoltaic cell, more particularly in a CdTe-based photovoltaic cell, the photoelectrically active CdTe layer of which is combined with a photoelectrically active layer of a different chemical nature selected from amorphous silicon, microcrystalline silicon, a copper-indium-gallium selenium alloy so as to form a tandem photovoltaic cell such as for example a tandem CdTe/CIGC or CdTe/amorphous or microcrystalline silicon cell, more particularly in the wavelength range extending from 400 nm to 850 nm, preferably in the wavelength range extending from 450 nm to 800 nm or from 400 nm to 800 nm, when this substrate is inserted in a CdTe-based photovoltaic cell comprising a photoelectrically active CdTe layer, it being possible for said CdTe layer to be alone, and, on the other hand, a good physicochemical resistance and mechanical strength. Furthermore, the transparent glass substrate according to the invention does not comprise any metallic layer, the latter having low transparency in the near infrared range. The conductive transparent glass substrate according to the invention may also undergo a heat treatment, said heat treatment not leading to a reduction in the electrical or optical properties of the substrate, or even improving them. Thus, the first barrier layer especially enables protection against pollution by migration of alkali metals coming from the glass sheet, the protective layer itself making it possible to prevent a deterioration of the electrical properties of the conductive functional layer especially by oxidation or contamination. The expression “layer based on” is understood to mean a layer predominantly containing the material, that is to say containing at least 50% by weight of this material. The inventors have determined that, surprisingly, the structure of the transparent glass substrate according to the invention applies more particularly for a transparent glass substrate comprising a functional layer based on doped zinc oxide, the latter being more sensitive to any heat treatment.

Thus, the invention is based on an entirely novel and inventive approach of selecting the thicknesses and compounds constituting the first barrier layer, the conductive functional layer and the protective layer of the conductive transparent glass substrate as a function of its use within a photovoltaic cell, more particularly within a CdTe-based photovoltaic cell.

The glass sheet on which the first barrier layer, the conductive functional layer and the protective layer are deposited preferably has a thickness of at least 0.35 mm. The glass sheet is preferably made of soda-lime-silica glass. More preferably, this is extra-clear soda-lime-silica glass. The term extra-clear denotes glass containing at most 0.020%, by weight of the glass, of total Fe expressed as Fe₂O₃, preferably at most 0.015% by weight, more preferably at most 0.010% by weight, the latter, due to its low content of Fe oxide, has a low light absorption, especially in the near infrared range. The use of the latter therefore makes it possible to obtain higher light transmission in the photovoltaic cell incorporating it. Advantageously, the glass sheet comprises an antireflection layer, for instance a layer based on porous silicon oxide, on the face opposite the face of the glass sheet on which the various barrier, conductive functional and protective layers are deposited.

According to one preferred embodiment in accordance with the invention, the conductive transparent glass substrate is such that the first barrier layer based on oxide, nitride or oxynitride, preferably based on nitride, has a thickness at least greater than or equal to 10 nm and at most less than or equal to 100 nm, preferably at least greater than or equal to 20 nm and at most less than or equal to 50 nm, the conductive functional layer based on doped zinc oxide or doped indium oxide, preferably based on doped zinc oxide, has a thickness at least greater than or equal to 200 nm, preferably at least greater than or equal to 300 nm, and at most less than or equal to 1200 nm and the protective layer based on nitride, oxynitride or oxycarbide, preferably based on nitride, has a thickness at least greater than or equal to 10 nm, preferably at least greater than or equal to 40 nm and at most less than or equal to 250 nm, preferably a thickness at least greater than or equal to 50 nm and at most less than or equal to 100 nm.

According to one preferred embodiment, the conductive transparent glass substrate according to the invention is such that the first barrier layer is based on oxide, nitride or oxynitride, preferably a nitride, of at least one element selected from titanium, aluminum, silicon, zinc, tin, indium, molybdenum, bismuth, tantalum, cerium, niobium, zirconium and tungsten, preferably from silicon or aluminum, a mixed oxide of at least two thereof, for example a mixed zinc-tin oxide, a mixed nitride of at least two thereof, for example a mixed silicon-aluminum nitride, or a mixed oxynitride of at least two thereof, most preferably the barrier layer is based on silicon oxide, nitride or oxynitride. The materials constituting the first barrier layer may also contain around 1% to 15%, as an atomic percentage, of additional elements originating from the target used when said layer is obtained by sputtering, these additional elements are in particular silicon, titanium, aluminum and boron. Nitrides are preferred to oxides and to oxynitrides since they do not contain oxygen, the possible diffusion of which is capable of influencing the properties, especially the electrical properties, of the conductive functional layer based on a doped oxide. Among the nitrides, silicon and aluminum nitrides are preferred due to their greater transparency and their better chemical resistance to oxidation, silicon nitride being more preferred due to its better chemical resistance to oxidation.

According to one embodiment in accordance with the invention, the conductive transparent glass substrate is such that the conductive functional layer is based on zinc oxide doped with one or more dopant elements selected from aluminum, gallium and boron, preferably from aluminum or gallium, or based on indium oxide doped with one or more dopant elements selected from tin, zinc, titanium, molybdenum and zirconium. Preferably, the conductive functional layer is based on zinc oxide doped with an element selected from aluminum or gallium, preferably the dopant element is aluminum. The functional layer based on doped zinc oxide or doped indium oxide has a degree of doping of m % by weight of oxide of a dopant element with m between 0.1% and 10.0%, preferably with m less than or equal to 6.0%, preferably with m less than or equal to 5.0%. When the functional layer is based on aluminum-doped zinc oxide, m is preferably less than or equal to 4.0%, more preferably less than or equal to 2.5%, most preferably m is greater than or equal to 0.5% and less than or equal to 2.5%. When the functional layer is based on gallium-doped zinc oxide, m is preferably between 2.0% and 6.0%.

According to one preferred embodiment in accordance with the invention, the conductive transparent glass substrate is such that the thickness of the conductive functional layer is at least greater than or equal to 200 nm, preferably at least greater than or equal to 300 nm, and at most less than or equal to 700 nm, preferably at most less than or equal to 500 nm for a conductive functional layer made of aluminum-doped zinc oxide having a degree of doping m equal to 2%.

According to another preferred embodiment in accordance with the invention, the conductive transparent glass substrate is such that the thickness of the conductive functional layer is at least greater than or equal to 700 nm and at most less than or equal to 1200 nm, preferably less than or equal to 900 nm for a conductive functional layer made of aluminum-doped zinc oxide having a degree of doping m equal to 0.5%.

According to one particular embodiment, the conductive transparent glass substrate according to the invention is such that the conductive functional layer based on doped zinc oxide consists of a stack of at least two layers of different electrical conductivity, one layer of high electrical conductivity and one layer of low electrical conductivity, such that the layer of high electrical conductivity is a layer based on zinc oxide doped to m % by weight of oxide of a first dopant element with m less than or equal to 6.0%, preferably with m less than or equal to 4.0%, more preferably with m equal to 2.0% and such that the layer of low electrical conductivity is a layer based on zinc oxide doped to (m/p) % by weight of oxide of a second dopant element with p greater than or equal to 2, preferably with p greater than or equal to 3, more preferably with p greater than or equal to 4. The dopant elements used for the layer of high electrical conductivity and the layer of low electrical conductivity may be of different chemical nature, preferably they are of the same nature. The thickness of the conductive functional layer based on doped zinc oxide is between 200 nm and 1200 nm. Preferably, the transparent conductive substrate according to the invention is such that the dopant element is selected from Al and/or Ga and/or B. Preferably, the dopant element is selected from Al and/or Ga. More preferably, the dopant element is Al.

According to one particular embodiment, the conductive transparent glass substrate according to the invention is such that the protective layer is based on nitride, oxynitride or oxycarbide, preferably based on a nitride, of at least one element selected from titanium, aluminum, silicon, zinc, tin, indium, molybdenum, bismuth, tantalum, cerium, niobium, zirconium and tungsten, preferably from aluminum and silicon, a mixed nitride of at least two thereof, for example a mixed silicon-aluminum nitride, a mixed oxynitride of at least two thereof, or a mixed oxycarbide of at least two thereof. More preferably, the protective layer is based on silicon nitride or aluminum nitride, a mixed silicon-aluminum nitride, preferably based on silicon nitride. Among the nitrides, silicon and aluminum nitrides are preferred due to their greater transparency and their better chemical resistance to oxidation, silicon nitride being more preferred due to its better chemical resistance to oxidation. Said protective layer based on silicon nitride may contain traces of aluminum, the term traces being understood to mean an amount of aluminum of less than or equal to 10%, as an atomic percentage, preferably less than or equal to 8%. Advantageously, the refractive index of the protective layer is greater than the refractive index of the conductive functional layer and less than the refractive index of the first layer deposited on the protective layer during the manufacture of the CdTe-based photovoltaic cell, this layer being made of CdS. Nitrides are preferred to oxynitrides and to oxycarbides since they do not contain oxygen, the possible diffusion of which is capable of influencing the properties, in particular the electrical properties, of the conductive functional layer based on doped oxide. Advantageously, the protective layer has a resistivity greater than or equal to 0.1 ohm/cm, preferably greater than or equal to 1 ohm/cm, the inventors having observed, surprisingly, that such a resistivity makes it possible to avoid preferential current passage points between the conductive functional layer and the CdTe layer and therefore makes it possible to extend the service life and increase the efficiency of the photovoltaic cell incorporating the conductive transparent glass substrate according to the invention. Just as surprisingly, the inventors have observed that the protective function and the resistive function of said protective layer could be obtained simultaneously if a good composition and a good thickness were chosen for this layer. Furthermore, the protective layer preferably has a roughness Ra less than or equal to 10 nm, more preferably less than 5 nm, Ra being the arithmetic mean roughness, the inventors having observed that, surprisingly, such a roughness makes it possible to avoid favored current passage points between the conductive functional layer and the CdTe layer and therefore makes it possible to extend the service life and increase the efficiency of the photovoltaic cell incorporating the conductive transparent glass substrate according to the invention.

According to one particular embodiment of the preceding embodiment, the nitride-based protective layer contains an oxygen content, expressed as an atomic percentage, of less than or equal to 10%, preferably less than or equal to 5%, more preferably less than or equal to 2%, most preferably equal to 0%.

According to one particular advantageous embodiment, the conductive transparent glass substrate according to the invention is such that it comprises a second barrier layer based on oxide or nitride, preferably based on nitride, inserted between the glass sheet and the first barrier layer based on oxide, nitride or oxynitride. Nitrides are preferred to oxides since they do not contain oxygen, the possible diffusion of which is capable of influencing the properties, particularly the electrical properties, of the conductive functional layer based on a doped oxide. Preferably, the second barrier layer is based on an oxide or nitride of at least one element selected from titanium, aluminum, silicon, zinc, tin, indium, molybdenum, bismuth, tantalum, cerium, niobium, zirconium, and tungsten, preferably from aluminum and silicon, a mixed oxide of at least two thereof, or a mixed nitride of at least two thereof. More preferably, the second barrier layer is based on a nitride of at least one element selected from silicon and aluminum, a mixed aluminum-silicon nitride, or based on an oxide of at least one element selected from titanium, tin, zirconium, and zinc, or a mixed oxide of at least two thereof. Most preferably, the second barrier layer is based on silicon nitride, titanium oxide, preferably doped with zirconium, on zinc oxide, on a mixed titanium-zirconium oxide or on a mixed zinc-tin oxide. When the second barrier layer is based on titanium oxide or tin oxide, the additional oxide(s) should preferably represent at least 5% by weight of the assembly and preferably at least 10%. In the case of a mixed titanium-zirconium oxide, the titanium oxide represents at least 50% by weight, preferably at least 55% by weight of the mixed oxide. In mixed zinc-tin oxides, the tin oxide represents at least 40% by weight, preferably at least 50% by weight of the mixed oxide. Apart from titanium oxide and other oxides listed above, the second barrier layer may also contain supplementary oxides practically indissociable from the preceding oxides. This is the case, in particular, for lanthanides such as yttrium oxide or hafnium oxide. When these additional oxides are present, their content remains relatively limited and does not exceed 8% by weight of the assembly and usually remains less than 5%. For instance, the example may be taken of a second barrier layer consisting of a mixed oxide containing 50% by weight of titanium oxide, 46% by weight of zirconium oxide and 4% by weight of yttrium oxide.

According to one particular embodiment of the preceding embodiment, the conductive transparent glass substrate according to the invention is such that the second barrier layer based on nitride or oxide, preferably based on nitride, has a thickness at most less than or equal to 30 nm, more preferably at most less than or equal to 20 nm. Advantageously, the second barrier layer has a refractive index greater than the refractive index of the first barrier layer. The expression “refractive index” is understood to mean the refractive index at a wavelength of 550 nm.

According to one preferred embodiment, the conductive transparent glass substrate according to the invention is such that the second barrier layer is based on silicon nitride, the first barrier layer is based on silicon oxide, the conductive functional layer is based on aluminum-doped zinc oxide and the protective layer is based on silicon nitride.

According to another embodiment, the conductive transparent glass substrate according to the invention is such that the second barrier layer is based on a mixed titanium-zirconium oxide, the first barrier layer is based on silicon oxide, the conductive functional layer is based on aluminum-doped zinc oxide and the protective layer is based on silicon nitride.

According to one particular embodiment, the conductive transparent glass substrate according to the invention is such that the second barrier layer is based on tin oxide, the first barrier layer is based on silicon oxide, the conductive functional layer is based on aluminum-doped zinc oxide and the protective layer is based on silicon nitride.

According to one preferred embodiment, the glass substrate according to the invention successively comprises a glass sheet, a first barrier layer made of an oxide, nitride or oxynitride of at least one element selected from silicon and aluminum, a conductive functional layer made of aluminum-doped zinc oxide, the degree of doping m being between 0.2% and 6.0% and a protective layer made of a nitride of an element selected from silicon and aluminum.

According to one particular embodiment, the transparent glass substrate according to the invention is such that a nitride-based blocking layer is inserted into the first barrier layer and the conductive functional layer, said blocking layer having a thickness at least greater than or equal to 5 nm and at most less than or equal to 15 nm, preferably a thickness at least greater than or equal to 8 nm and at most less than or equal to 12 nm, more preferably equal to 10 nm. Preferably, the blocking layer is based on a nitride of at least one element selected from titanium, aluminum, silicon, zinc, tin, indium, molybdenum, bismuth, tantalum, cerium, niobium, zirconium and tungsten, preferably from aluminum and silicon, more preferably the element selected is silicon, most preferably the blocking layer is made of silicon nitride, it being possible for said silicon nitride blocking layer to contain around 1% to 15%, as an atomic percentage, of additional elements originating from the target used when said layer is obtained by sputtering, these additional elements are in particular titanium, aluminum and boron, preferably aluminum. The inventors have determined, surprisingly, that the presence of said nitride-based blocking layer makes it possible to control the diffusion of oxygen between the first barrier layer and the conductive functional layer and thus reduce the risks of oxidation of the functional layer. The materials constituting the blocking layer may also contain around 1% to 15%, as an atomic percentage, of additional elements originating from the target used when said layer is obtained by sputtering, these additional elements are in particular silicon, titanium, aluminum and boron.

According to one particular embodiment, the conductive transparent glass substrate according to the invention comprises, consists of, or even essentially consists of, successively, a glass sheet, a first barrier layer based on oxide, nitride or oxynitride, a conductive functional layer based on doped zinc oxide or doped indium oxide, preferably based on doped zinc oxide, and a protective layer based on nitride, oxynitride or oxycarbide, the first barrier layer based on oxide, nitride or oxynitride having a thickness of at least greater than or equal to 10 nm and at most less than or equal to 100 nm, the conductive functional layer based on doped zinc oxide or doped indium oxide having a thickness at least greater than or equal to 200 nm, preferably greater than or equal to 300 nm, and at most less than or equal to 1200 nm and the protective layer having a thickness of at least greater than or equal to 10 nm, preferably greater than or equal to 40 nm and at most less than or equal to 250 nm. According to one alternative embodiment, the transparent glass substrate comprises, consists of, or even essentially consists of, successively, a glass sheet, a second barrier layer based on nitride or oxide, a first barrier layer based on oxide, nitride or oxynitride, a conductive functional layer based on doped zinc oxide or doped indium oxide, preferably based on doped zinc oxide, and a protective layer based on nitride, the second barrier layer based on nitride or oxide having a thickness at most less than or equal to 30 nm, more preferably less than or equal to 20 nm, the first barrier layer based on oxide, nitride or oxynitride having a thickness at least greater than or equal to 10 nm and at most less than or equal to 100 nm, the conductive functional layer based on doped zinc oxide or doped indium oxide having a thickness at least greater than or equal to 200 nm, preferably greater than or equal to 300 nm, and at most less than or equal to 1200 nm and a protective layer having a thickness at least greater than or equal to 10 nm, preferably greater than or equal to 40 nm and at most less than or equal to 250 nm. According to one alternative embodiment, the transparent glass substrate comprises, consists of, or even essentially consists of, successively, a glass sheet, a second barrier layer based on nitride or oxide, a first barrier layer based on oxide, nitride or oxynitride, a blocking layer based on nitride, a conductive functional layer based on doped zinc oxide or based on doped indium oxide, preferably based on doped zinc oxide, and a protective layer based on nitride, the second barrier layer based on nitride or oxide having a thickness at most less than or equal to 30 nm, more preferably less than or equal to 20 nm, the first barrier layer based on oxide, nitride or oxynitride having a thickness at least greater than or equal to 10 nm and at most less than or equal to 100 nm, the blocking layer based on nitride having a thickness at least greater than or equal to 5 nm and at most less than or equal to 15 nm, preferably a thickness at least greater than or equal to 8 nm and at most less than or equal to 12 nm, more preferably equal to 10 nm, the conductive functional layer based on doped zinc oxide or on indium oxide, preferably based on zinc oxide, having a thickness at least greater than or equal to 200 nm, preferably at least greater than or equal to 300 nm, and at most less than or equal to 1200 nm and a protective layer having a thickness at least greater than or equal to 10 nm, preferably at least greater than or equal to 40 nm and at most less than or equal to 250 nm.

Another subject of the invention relates to the process for manufacturing the transparent conductive glass substrate according to the invention. The process of manufacturing the transparent conductive substrate according to the invention is a process according to which all of the various layers—second barrier layer, first barrier layer, blocking layer, conductive functional layer and protective layer—are deposited on a glass sheet by a vacuum deposition technique, preferably by a magnetron sputtering technique. The magnetron sputtering technique makes it possible to obtain layers that have a low roughness.

According to one alternative implementation, the process for manufacturing the transparent conductive glass substrate according to the invention is a process according to which the second barrier layer, for example made of SiOₓC_{y}, is deposited on a glass sheet by a CVD (Chemical Vapor Deposition) deposition technique, which is optionally plasma-enhanced, the other layers, namely the first barrier layer, the blocking layer, the conductive functional layer and the protective layer being deposited by a vacuum deposition technique, preferably by a magnetron sputtering technique.

According to one advantageous implementation of the invention, the process for manufacturing the conductive transparent glass substrate is such that it comprises the following successive steps of deposition by vacuum techniques:
deposition onto a glass sheet of a first barrier layer based on oxide, nitride or oxynitride, preferably based on nitride,
deposition of a conductive functional layer based on doped indium oxide or doped zinc oxide, preferably based on doped zinc oxide,
deposition of a protective layer based on nitride, oxynitride or oxycarbide, preferably based on nitride.

According to one alternative implementation, the process for manufacturing the conductive transparent glass substrate is such that it comprises the following successive steps of deposition by vacuum techniques:
deposition onto a glass sheet of a second barrier layer based on nitride or oxide, preferably based on nitride,
deposition of a first barrier layer based on oxide, nitride or oxynitride, preferably based on nitride,
deposition of a conductive functional layer based on doped zinc oxide or doped indium oxide, preferably based on doped zinc oxide,
deposition of a protective layer based on nitride, oxynitride or oxycarbide, preferably based on nitride.

According to one alternative implementation, the process for manufacturing the conductive transparent glass substrate is such that it comprises the following successive steps of deposition by vacuum techniques:
deposition onto a glass sheet of a second barrier layer based on nitride or oxide, preferably based on nitride,
deposition of a first barrier layer based on oxide, nitride or oxynitride, preferably based on nitride,
deposition onto a glass sheet of a blocking barrier layer based on nitride,
deposition of a conductive functional layer based on doped zinc oxide or doped indium oxide, preferably based on doped zinc oxide,
deposition of a protective layer based on nitride, oxynitride or oxycarbide, preferably based on nitride.

According to one advantageous implementation, the process for manufacturing the conductive transparent glass substrate is such that the deposition of the various layers is carried out on a glass sheet at ambient temperature.

According to one advantageous implementation, the process for manufacturing the conductive transparent glass substrate is such that it comprises, after the deposition of the layers, a step of annealing at a temperature at least equal to 500° C., preferably at least equal to 600° C., most preferably at a temperature at least equal to 650° C., for a time at least equal to 7 minutes, preferably at least equal to 7 minutes 30 seconds. Alternatively, the step of annealing the conductive transparent glass substrate may be carried out during the process for manufacturing the CdTe-based photovoltaic cell. Indeed, obtaining layers made of CdS and made of CdTe may require heating the conductive transparent glass substrate and/or a step of annealing the layers made of CdS and/or made of CdTe at a temperature between 400° C. and 600° C., or even between 400° C. and 500° C., the annealing time then being at least 30 minutes, or even one hour at least. This annealing step makes it possible to obtain an improvement in the electrical properties of the conductive functional layer. This annealing making it possible, on the one hand, to obtain an improvement in the electrical properties resulting in particular in a surface resistance of less than or equal to 10Ω/□ and, on the other hand, to obtain a light transmission, Tl, through the conductive transparent glass substrate according to the invention, at least equal to 80%, said substrate consisting of a sheet of glass of clear soda-lime-silica float glass type having a thickness of 4 mm, measured with a source in accordance with the CIE standard D65 “daylight” illuminant and under a solid angle of 2°, according to the EN410 standard.

According to one alternative implementation, the process for manufacturing the transparent glass substrate is such that the glass sheet is brought to a temperature at least equal to 300° C., preferably at least equal to 350° C., before the deposition of the various layers, preferably before the deposition of the conductive functional layer based on doped zinc oxide or doped indium oxide, preferably based on doped zinc oxide. It being possible for the glass sheet to be preheated using infrared lamps.

Another subject of the invention relates to a photovoltaic cell, more particularly a CdTe-based photovoltaic cell comprising the conductive transparent glass substrate according to the invention.

The invention also relates to a process for manufacturing a photovoltaic cell based on CdTe such that it successively comprises the following deposition steps:
vacuum deposition onto a glass sheet of a first barrier layer based on oxide, nitride or oxynitride, preferably based on nitride,
vacuum deposition of a conductive functional layer based on doped zinc oxide or doped indium oxide, preferably doped zinc oxide,
vacuum deposition of a protective layer based on nitride, oxynitride or oxycarbide, preferably based on nitride,
deposition of a CdS layer,
deposition of a CdTe layer,
deposition of the counter electrode.

The layers made of CdTe and/or made of CdS may be deposited on a substrate brought to a higher temperature, the expression higher temperature being understood to mean a temperature at least equal to 600° C. Moreover, the CdTe and/or CdS layers may also be annealed after deposition, the annealing temperature being between 400° C. and 600° C., or even between 400° C. and 500° C.

According to one advantageous method of implementation, the process for manufacturing a CdTe-based photovoltaic cell is such that the deposition of the barrier, conductive functional and protective layers is carried out at ambient temperature, the annealing step that makes it possible to obtain an improvement in the electrical properties of the conductive functional layer being carried out simultaneously with the annealing of the CdS and/or CdTe layers, the annealing temperature being between 400° C. and 600° C.

One subject of the invention also relates to the use of the conductive glass substrate as a front face electrode, otherwise referred to as a sun side electrode, of a photovoltaic cell, more particularly of a CdTe-based photovoltaic cell.

### 5. LISTS OF FIGURES

Other features and advantages of the invention will appear more clearly on reading the following description of one preferred embodiment, given as a simple illustrative and nonlimiting example, and of the appended drawings, among which:

FIG. 1 represents a conductive transparent glass substrate according to the invention successively comprising a glass sheet (1), a first barrier layer based on oxide, nitride or oxynitride (3), a conductive functional layer based on doped zinc oxide or doped indium oxide (4) and a protective layer based on nitride, oxynitride or oxycarbide (5);

FIG. 2 represents a conductive transparent glass substrate according to the invention successively comprising a glass sheet (1), a second barrier layer based on nitride or oxide (2), a first barrier layer based on oxide, nitride or oxynitride (3), a conductive functional layer based on doped zinc oxide or doped indium oxide (4) and a protective layer based on nitride, oxynitride or oxycarbide (5);

FIG. 3 represents a conductive transparent glass substrate according to the invention successively comprising a glass sheet (1), a second barrier layer based on nitride or oxide (2), a first barrier layer based on oxide, nitride or oxynitride (3), a blocking layer (6), a conductive functional layer based on doped zinc oxide or doped indium oxide (4) and a protective layer based on nitride, oxynitride or oxycarbide (5);

FIG. 4 represents a CdTe-based photovoltaic cell according to the invention successively comprising a glass sheet (1), a second barrier layer based on nitride or oxide (2), a first barrier layer based on oxide, nitride or oxynitride (3), a blocking layer (6), a conductive functional layer based on doped zinc oxide or doped indium oxide (4), a protective layer based on nitride, oxynitride or oxycarbide (5), a CdS layer (7), a CdTe layer (8) and a counter electrode (9), the photovoltaic cell being provided with an antireflection layer (10) on the face of the glass sheet opposite that bearing the CdTe layer. It should be noted that a supplementary layer may optionally be deposited between the CdTe layer and the counter electrode, said layer is not represented in FIG. 4.

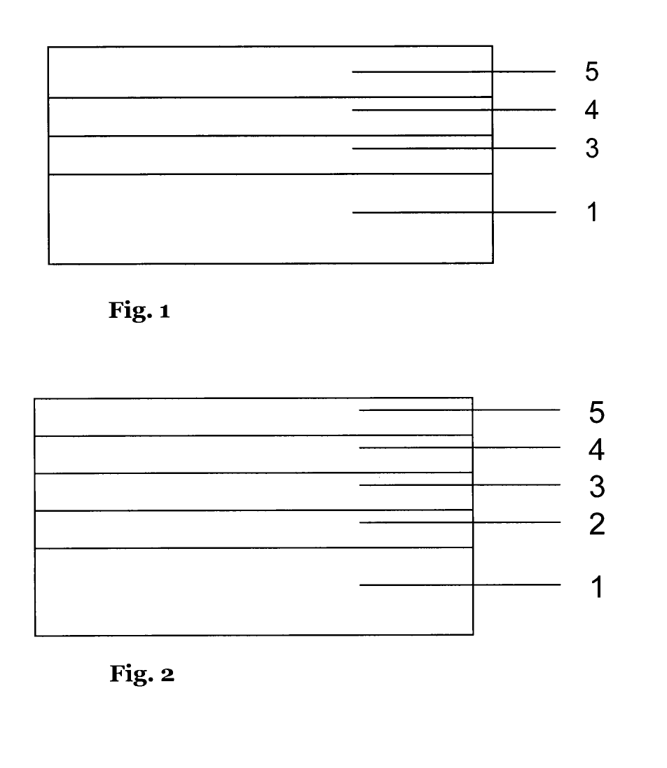

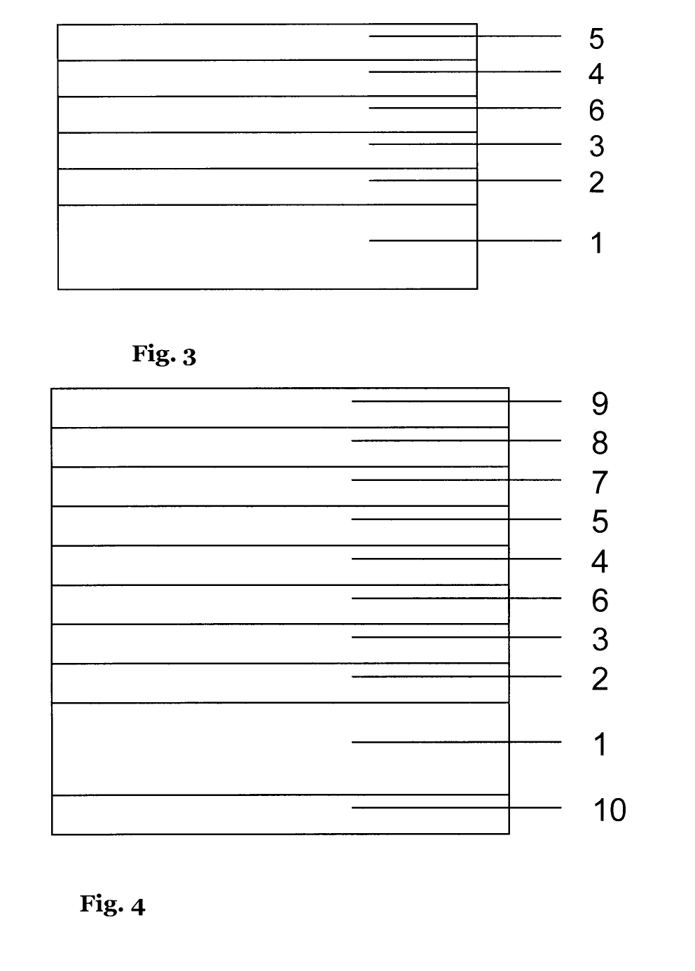

### 6. DESCRIPTION OF ONE EMBODIMENT OF THE INVENTION

Table 1 presents five columns with examples of a conductive transparent glass substrate not in accordance with the invention.

The symbols SiN, AZO, ZSO5 respectively represent silicon nitride of formula Si₃N₄, aluminum-doped zinc oxide, mixed zinc-tin oxide in proportions by weight of 48% of zinc and 52% of tin in the cathode. These various materials were deposited according to the following conditions: SiN: 5 mtorr, 2.32 W/cm², atmosphere: 50/50 mixtures of Ar/O₂; AZO: 5 mtorr, 1.16 W/cm², atmosphere: 100% Ar; ZSO5: 5 mtorr, 1.16 W/cm², atmosphere: 20/80 mixture of Ar/O₂.

TABLE 1

| | | Examples not in accordance | | | | |
|---|---|---|---|---|---|---|
| | | with the invention | | | | |
| | | 1R | 2R | 3R | 4R | 5R |
| Second | Thickness (nm) | — | — | — | — | — |
| barrier | Composition | — | — | — | — | — |
| layer | Temperature of | — | — | — | — | — |
| | the glass sheet | | | | | |
| | during the | | | | | |
| | deposition (° C.) | | | | | |
| First | Thickness (nm) | — | — | 80 | 30 | 30 |
| barrier | Composition | — | — | SiN | SiN | ZSO5 |
| layer | Temperature of | — | — | 25 | 25 | 25 |
| | the glass sheet | | | | | |
| | during the | | | | | |
| | deposition (° C.) | | | | | |
| Conductive | Thickness (nm) | 1000 | 1000 | 900 | 910 | 910 |
| functional | Composition | AZO | AZO | AZO | AZO | AZO |
| layer | | 2.0% | 2.0% | 2.0% | 1.0% | 1.0% |
| | Temperature of | 25 | 350 | 350 | 350 | 350 |
| | the glass sheet | | | | | |
| | during the | | | | | |
| | deposition (° C.) | | | | | |
| Protective | Thickness (nm) | — | — | — | 80 | 80 |
| layer | Composition | — | — | — | ZSO5 | ZSO5 |
| | Temperature of | — | — | — | 25 | 25 |
| | the glass sheet | | | | | |
| | during the | | | | | |
| | deposition (° C.) | | | | | |

Table 2 presents three columns with examples of a transparent glass substrate in accordance with the invention. The deposition conditions for the various materials are the same those used for the examples not in accordance with the invention.

TABLE 2

| | | Examples in accordance | | |
|---|---|---|---|---|
| | | with the invention | | |
| | | 1 | 2 | 3 |
| Second barrier | Thickness (nm) | — | — | — |
| layer | | — | — | |
| | Composition | — | — | — |
| | Temperature of the | — | — | — |
| | glass sheet during | | | |
| | the deposition (° C.) | | | |
| First barrier | Thickness (nm) | 80 | 80 | 80 |
| layer | Composition | SiN | SiN | SiN |
| | Temperature of the | 25 | 25 | 25 |
| | glass sheet during | | | |
| | the deposition (° C.) | | | |
| Conductive | Thickness (nm) | 900 | 900 | 900 |
| functional | Composition | AZO | AZO | AZO |
| layer | | 2.0% | 2.0% | 2.0% |
| | Temperature of the | 350 | 350 | 350 |
| | glass sheet during | | | |
| | the deposition (° C.) | | | |
| Protective | Thickness (nm) | 300 | 200 | 100 |
| layer | Composition | SiN | SiN | SiN |
| | Temperature of the | 25 | 25 | 25 |
| | glass sheet during | | | |
| | the deposition (° C.) | | | |

Table 3 presents the electrical and optical properties measured and compared to examples 1R, 2R, 3R, 4R and 5R not in accordance with the invention before and after annealing at 670° C. for 7 minutes 30 seconds; the improvement in the properties and the better resistance to the annealing step of the examples in accordance with the invention is noted.

TABLE 3

| | | | | | After annealing (670° C. for | | | |
|---|---|---|---|---|---|---|---|---|
| | Before annealing | | | | 7 minutes 30 seconds) | | | |
| | | | n | | | | n | |
| | T(400-800 nm)* | R | (E20/ | μ | T(400-800 nm)* | R | (E20/ | μ |
| Example | (%) | (Ω/□) | cm³) | (cm²/Vs) | (%) | (Ω/□) | cm³) | (cm²/Vs) |
| 1R | 71.7 | 7.6 | — | — | — | 500.0 | — | — |
| 2R | 83.1 | 4.3 | — | — | — | 140.0 | — | — |
| 3R | 83.4 | 4.1 | — | — | — | 20.0 | — | — |
| 4R | — | 6.6 | 3.4 | 30.6 | — | 100.0 | 12.3 | 5.4 |
| 5R | — | 10.6 | 3.1 | 21.5 | — | 1000.0 | 96.5 | 0.4 |
| 1 | — | 10.5 | 2.83 | 23.3 | 78.3 | 7.3 | 2.4 | 40.2 |
| 2 | — | 12.7 | 2.57 | 21.2 | 77.7 | 8.2 | 2.2 | 38.2 |
| 3 | — | — | — | — | 78.1 | 5.7 | 2.7 | 44.9 |

*T(400-800 nm)is the mean transmittance in a wavelength range between 400 and 800 nm.

Table 4 presents the mean reflection over a wavelength range extending from 400 to 800 nm of various conductive transparent glass substrates in accordance with the invention, said substrates being covered with a CdS layer and a CdTe layer. These reflection values were obtained by simulation using the CODE program from the brand W. Theiss Hard- and Software.

TABLE 4

| | Examples | | | | | | |
|---|---|---|---|---|---|---|---|
| | 4 | 5 | 6 | 7 | 8 | 9 | 10 |
| | Thickness (nm) | | | | | | |
| CdTe | 2000.0 | 2000.0 | 2000.0 | 2000.0 | 2000.0 | 2000.0 | 2000.0 |
| CdS | 100.0 | 100.0 | 100.0 | 100.0 | 100.0 | 100.0 | 100.0 |
| SiN | 67.0 | 73.9 | 67.1 | 70.8 | 67.0 | 68.8 | 67.8 |
| AZO | 300.0 | 400.0 | 500.0 | 600.0 | 700.0 | 800.0 | 900.0 |
| SiO₂ | 32.5 | 28.4 | 29.0 | 28.1 | 27.6 | 28.0 | 27.2 |
| SiN | 13.6 | 16.5 | 14.3 | 16.3 | 14.9 | 16.4 | 15.5 |
| Glass | 3 × 10⁶ | 3 × 10⁶ | 3 × 10⁶ | 3 × 10⁶ | 3 × 10⁶ | 3 × 10⁶ | 3 × 10⁶ |
| sheet | | | | | | | |
| Mean | 0.0632 | 0.0639 | 0.0622 | 0.0632 | 0.0611 | 0.0621 | 0.0602 |
| reflection | | | | | | | |
| between | | | | | | | |
| 400 nm and | | | | | | | |
| 800 nm | | | | | | | |

Table 5 presents supplementary examples in accordance with the invention, and table 6 presents the change in the surface resistance expressed in ohms/square before and after an annealing carried out respectively at 500° C. and 670° C. for 7 minutes 30 seconds.

TABLE 5

| | | Examples in accordance | | | | | | |
|---|---|---|---|---|---|---|---|---|
| | | with the invention | | | | | | |
| | | 11 | 12 | 13 | 14 | 15 | 16 | 17 |
| Second | Thickness | — | — | — | 15.9 | 15.5 | 15.5 | 15.9 |
| barrier | (nm) | | | | | | | |
| Layer | Composition | — | — | — | SiN | SiN | SiN | SiN |
| | Temperature | — | — | — | 25 | 25 | 25 | 25 |
| | of the glass | | | | | | | |
| | sheet during | | | | | | | |
| | the deposition (° C.) | | | | | | | |
| First | Thickness | 80.0 | 80.0 | 80.0 | 29.0 | 28.4 | 28.4 | 28.9 |
| barrier | (nm) | | | | | | | |
| layer | Composition | SiN | SiN | SiN | SiO₂ | SiO₂ | SiO₂ | SiO₂ |
| | Temperature | 25 | 25 | 25 | 25 | 25 | 25 | 25 |
| | of the glass | | | | | | | |
| | sheet during | | | | | | | |
| | the deposition (° C.) | | | | | | | |
| Conductive | Thickness | 900.0 | 900.0 | 900.0 | 500.0 | 900.0 | 900.0 | 700.0 |
| functional | (nm) | | | | | | | |
| layer | Composition | AZO | AZO | AZO | AZO | AZO | AZO | AZO |
| | | 2.0% | 2.0% | 2.0% | 2.0% | 2.0% | 0.5% | 2.0% |
| | Temperature | 350 | 350 | 350 | 350 | 350 | 350 | 350 |
| | of the glass | | | | | | | |
| | sheet during | | | | | | | |
| | the deposition (° C.) | | | | | | | |
| Protective | Thickness | 60.0 | 40.0 | 20.0 | 55.1 | 53.7 | 53.7 | 53.7 |
| layer | (nm) | | | | | | | |
| | Composition | SiN | SiN | SiN | SiN | SiN | SiN | SiN |
| | Temperature | 25 | 25 | 25 | 25 | 25 | 25 | 25 |
| | of the glass | | | | | | | |
| | sheet during | | | | | | | |
| | the deposition (° C.) | | | | | | | |
| T(400-800 nm) | | 73.6 | 74.5 | 76.4 | 78.2 | 76.4 | 80.0 | 77.2 |
| (%) | | | | | | | | |

TABLE 6

| | Surface resistance (Ω/□) | | |
|---|---|---|---|
| Examples | Before | Annealing at 500° C. | Annealing at 600° C. |
| from table 5 | annealing | for 7 min 30 sec | for 7 min 30 sec |
| 11 | 8.4 | 3.7 | 3.5 |
| 12 | 8.1 | 3.7 | 3.3 |
| 13 | 8.3 | 3.7 | 3.5 |
| 14 | 16.9 | — | 7.5 |
| 15 | 8.8 | 6.0 | 3.4 |
| 16 | 26.4 | 14.7 | 9.7 |
| 17 | 11.8 | 6.0 | 4.7 |

A significant reduction in the surface resistance is observed after a step of annealing at 500° C., this reduction being at least 310. It is also noted that an annealing carried out at a temperature of 670° C. makes it possible to obtain surface resistance values that are slightly lower, by at least 5%, than those observed after annealing carried out at 500° C., which particularly illustrates the good quality of the barrier layers.

The physicochemical and mechanical durability of the transparent substrates according to the invention is measured by a resistance to delamination. The test used for measuring the resistance to delamination is known under the acronym DHB for damp heat bias. This test consists in subjecting the samples coated with thin layers to simultaneous electrical and thermal attacks. The coated samples are heated to a certain temperature, said temperature having to remain stable, and are then subjected to an electric field. The conditions used by the inventors are the following: the sample to be tested is brought into contact with a graphite electrode acting as the anode and an aluminum-covered copper electrode acting as the cathode, the electrodes being placed on either side of the sample tested. The cathode is brought into contact with the sample tested on the uncovered side of the glass sheet, the anode being brought into contact with the sample tested on the covered side. The parameters of the test are set according to the following modalities: a potential difference of 500 V is applied between the two electrodes, the sample being previously brought to a stable temperature of 165° C. The voltage or potential difference is applied for 15 minutes. After cooling to ambient temperature, the sample is then placed in an atmosphere saturated with water vapor (100% relative humidity) enabling continuous condensation on the face of the glass sheet covered by the various layers. The apparatus used for the continuous water vapor condensation test is of “Cleveland Cabinet” type, the latter and the methodology used satisfying the standard ISO 6720-1: 1998 (the temperature of the water is 55° C.+/−2° C. and the temperature of the water vapor is 50° C.+/−2° C.). The test is considered to be successful when the sample has a delamination ranging from 0% to 6% of the total surface. Examples 11, 12 and 15 were subjected to the DHB test and passed.

1. A conductive transparent glass substrate, successively comprising:
a glass sheet,
a first barrier layer based on oxide, nitride or oxynitride,
a conductive functional layer based on doped zinc oxide or doped indium oxide, and
a protective layer based on nitride, oxynitride or oxycarbide,
wherein:
the first barrier layer has a thickness of at least 10 nm and at most 100 nm,
the conductive functional layer has a thickness of at least 200 nm and at most 1200 nm,
the protective layer has a thickness of at least 10 nm and at most 250 nm, and
the conductive transparent glass substrate does not comprise a metallic layer.

2. The conductive transparent glass substrate of claim 1, wherein the first barrier layer is based on oxide, nitride or oxynitride of at least one element selected from the group consisting of titanium, aluminum, silicon, zinc, tin, indium, molybdenum, bismuth, tantalum, cerium, niobium, zirconium and tungsten.

3. The conductive transparent glass substrate of claim 1, wherein the conductive functional layer is based on zinc oxide doped with one or more dopant elements selected from the group consisting of aluminum, gallium and boron or based on indium oxide doped with one or more dopant elements selected from the group consisting of tin, zinc, titanium, molybdenum and zirconium.

4. The conductive transparent glass substrate of claim 1, wherein the protective layer is based on nitride, oxynitride or oxycarbide of at least one element selected from the group consisting of titanium, aluminum, silicon, zinc, tin, indium, molybdenum, bismuth, tantalum, cerium, niobium, zirconium and tungsten.

5. The conductive transparent glass substrate claim 1, further comprising:
a second barrier layer based on nitride or oxide inserted between the glass sheet and the first barrier layer.

6. The conductive transparent glass substrate of claim 5, wherein the second barrier layer has a thickness of at most 30 nm.

7. The conductive transparent glass substrate of claim 5, wherein
the second barrier layer is based on silicon nitride,
the first barrier layer is based on silicon oxide,
the conductive functional layer is based on aluminum-doped zinc oxide, and
the protective layer is based on silicon nitride.

8. The conductive transparent glass substrate of claim 1, such that wherein
a nitride-based blocking layer is inserted into the first barrier layer and the conductive functional layer, and
the nitride-based blocking layer has a thickness of at least 5 nm and at most 15 nm.

9. A process for manufacturing the conductive transparent glass substrate of claim 1, the process comprising, by vacuum techniques:
(i) deposition depositing onto the glass sheet the first barrier layer based on oxide, nitride or oxynitride,
(ii) subsequently depositing the conductive functional layer based on doped zinc oxide or doped indium oxide, and
(iii) a subsequently depositing the protective layer based on nitride, oxynitride or oxycarbide,
thereby obtaining the conductive transparent glass substrate.

10. A process for manufacturing the conductive transparent glass substrate of claim 5, the process comprising, by vacuum techniques:
(i) deposition depositing onto the glass sheet the second barrier layer based on nitride or oxide,
(ii) subsequently depositing the first barrier layer based on oxide, nitride or oxynitride,
(iii) subsequently depositing the conductive functional layer based on doped zinc oxide or doped indium oxide, and
(iv) subsequently depositing the protective layer based on nitride, oxynitride or oxycarbide,
thereby obtaining the conductive transparent glass substrate.

11. The process of claim 9, wherein said depositing (i), (ii), and (iii) are carried out at an ambient temperature.

12. The process of claim 9, further comprising:
after said depositing (iii), annealing at a temperature of at least 500° C., for a period of at least 7 minutes.

13. The process of claim 9, wherein the glass sheet is brought to a temperature of at least 300° C. before said depositing (ii).

14. A photovoltaic cell, comprising: the conductive transparent glass substrate of claim 1.

15. A process for manufacturing a photovoltaic cell based on CdTe, the process comprising:
vacuum depositing onto a glass sheet a first barrier layer based on oxide, nitride or oxynitride,
subsequently vacuum depositing a conductive functional layer based on doped zinc oxide or doped indium oxide,
subsequently vacuum depositing a nitride-based protective layer,
subsequently depositing a CdS layer,
subsequently depositing a CdTe layer, and
subsequently depositing a counter electrode,
thereby obtaining the photovoltaic cell based on CdTe.

16. A front face electrode, comprising the conductive transparent glass substrate of claim 1, wherein the front face electrode is a sun side electrode of a photovoltaic cell.

17. The process of claim 10, wherein said depositing (i), (ii), (iii), and (iv) are carried out at an ambient temperature.

18. The process of claim 10, further comprising:
after said depositing (iv), annealing at a temperature of at least 500° C., for a period of at least 7 minutes.

19. The process of claim 10, wherein the glass sheet is brought to a temperature of at least 300° C. before said depositing (iii).
